(19) United States
(12) Patent Application Publication
(10) Pub. No.: US 2009/0065048 A1
(43) Pub. Date: Mar. 12, 2009

(54) Hybrid Photolytic Fuel Cell

(75) Inventors: Neil Paul Dasgupta, Menlo Park, CA (US); Timothy Peter Holme, Palo Alto, CA (US); Friedrich B. Prinz, Woodside, CA (US)

Correspondence Address: DEMONT & BREYER, LLC, 100 COMMONS WAY, Ste. 250, HOLMDEL, NJ, 07733, US

(73) Assignee: The Board of Trustees of the Leland Stanford Junior University, Palo Alto, CA (US)

(21) Appl. No.: 11/873,274

(22) Filed: Oct. 16, 2007

Related U.S. Application Data
(60) Provisional application No. 60/862,008, filed on Oct. 18, 2006.

(51) Int. Cl. B05D 3/02; H01L 31/00

(52) U.S. Cl. 136/256; 427/115; 427/540

(57) ABSTRACT

An apparatus for providing electrical energy by utilizing energy from absorbed light to dissociate water and thereby provide free electrons is disclosed. In some embodiments, the apparatus comprises a fuel cell having a photolytic front end, a proton-conducting layer, and a catalytic cathode. The photolytic front end uses energy from light to dissociate water molecules into protons and electrons, the proton-conducting layer conducts protons to the catalytic cathode and forces the electrons to travel through an external electrical circuit, and the catalytic cathode recombines the protons and electrons with oxygen to reform water molecules.

### CROSS REFERENCE TO RELATED APPLICATIONS

The underlying concepts, but not necessarily the language, of the following case is incorporated by reference:

U.S. Patent Application Ser. No. 60/862,008, filed 18 Oct. 2006. If there are any contradictions or inconsistencies in language between this application and one or more of the cases that have been incorporated by reference that might affect the interpretation of the claims in this case, the claims in this case should be interpreted to be consistent with the language in this case.

### FIELD OF THE INVENTION

The present invention relates to energy conversion devices in general, and, more particularly, to fuel cells.

### BACKGROUND OF THE INVENTION

Fuel cells and photovoltaic devices are attractive alternatives to conventional means of providing electrical energy. In many cases, these devices can provide electrical energy without substantial generation of pollutants and without the need for the combustion of fossil fuels.

A photovoltaic device provides electrical energy by means of a conversion of light energy. The solar cell is perhaps the most prominent example of a photovoltaic device. A photovoltaic device commonly comprises a semiconductor that absorbs incident light, such as sunlight. The absorbed light gives its energy to electrons within the semiconductor, which excites them into the conduction band of the semiconductor. When a voltage is applied to the semiconductor, the excited electrons are enabled to flow and give rise to an electric current. This electric current can be used to power an external device or charge an electrical storage device, such as a battery. Unfortunately, photovoltaic devices tend to be quite expensive. In addition, photovoltaic devices are typically quite inefficient.

A fuel cell provides electrical energy by means of an electrochemical conversion device, similar to a battery. Unlike a battery, however, it is designed for continuous replenishment of the reactants consumed. A fuel cell produces electricity from fuel and oxygen provided externally, as opposed to the limited internal energy storage capacity of a battery. Fuel cells offer the potential for powering electronics and the like without substantial generation of pollutants. In addition, typical fuel cells operate without hydrocarbon-based fuels, such as oil or gasoline.

Perhaps the most attractive type of fuel cell is the hydrogen/oxygen proton exchange membrane fuel cell. A hydrogen/oxygen fuel cell typically comprises a proton-conducting membrane (e.g., an electrolyte) that separates an anode and a cathode. Typically, hydrogen is delivered to the fuel cell anode, which comprises a catalyst that accelerates a first chemical reaction wherein H₂ molecules dissociate into protons and electrons (i.e., H₂→2H⁺+2e⁻). The protons are conducted through the membrane to the cathode, while the electrons are forced to travel through an electrical circuit that is connected between the anode and cathode. At the cathode, another catalyst accelerates a second chemical reaction wherein water molecules are formed from oxygen molecules that combine with the conducted protons and electrons upon their return from the external circuit (i.e., O₂+4H⁺+4e⁻→2H₂O). In an ideal case, the only byproduct of the operation of the fuel cell is water (in either liquid or gas phase).

There are, however, several problems associated with conventional fuel cells. First, it can be difficult to safely and efficiently deliver hydrogen to the anode. Second, a storage vessel for hydrogen is often necessary in order to ensure a steady supply of H2 molecules to the anode. As a result, the capacity of the fuel cell is limited. Third, the need to store quantities of volatile hydrogen can lead to safety issues and added cost. Fourth, these fuel cells are not well suited to remote operation since the hydrogen must be replenished once depleted.

A need exists, therefore, for an energy conversion device that avoids at least some of the drawbacks of the prior-art.

### SUMMARY OF THE INVENTION

The present invention provides a fuel cell for providing electrons to an external circuit that avoids some of the costs and disadvantages of the prior art.

A fuel cell in accordance with the present invention utilizes energy gained from the absorption of light to dissociate water into byproducts that include protons and electrons. The fuel cell provides electric current for an external circuit that is electrically connected to the fuel cell. Electrons are provided to the circuit via an anode and return back to the fuel cell via a catalytic cathode. At the catalytic cathode, the electrons recombine with the protons and oxygen to reform water molecules.

The illustrative embodiment comprises a photolytic layer having an anion-vacancy concentration gradient, a proton-conducting layer (e.g., an electrolyte, etc.) that is non-conductive for electrons, and an anode and catalytic cathode for connection with an external circuit.

The photolytic layer composes the front end of the fuel cell. It utilizes energy from absorbed light to dissociate water molecules, and to thereby provide electrons and protons to the anode and proton-conducting layer. The proton-conducting layer is non-conductive for electrons; therefore, the electrons at the anode are forced through the external circuit. The protons are conducted from the photolytic layer to the catalytic cathode through the proton-conducting layer. At the catalytic cathode, the protons recombine with oxygen and electrons returning from the external circuit to reform water molecules.

The anion-vacancy concentration gradient in the photolytic layer is formed by heating the photolytic layer to a high temperature, applying an electric field across the photolytic layer, and reducing the temperature while in the presence of the applied electric field.

In some embodiments of the present invention, the photolytic layer comprises a plurality of sub-layers, each of which is modified to efficiently absorb a different portion of the visible light spectrum. As a result, substantially the entire visible light spectrum can be efficiently absorbed by the collective sub-layers.

A fuel cell in accordance with the illustrative embodiment comprises: a photolytic layer, wherein the photolytic layer is in a solid state; and a proton-conducting layer, wherein the proton-conducting layer is in a solid state, and wherein the proton-conducting layer is substantially non-conductive for electrons; wherein at least one of water and hydroxide molecules dissociate at a surface of the photolytic layer to provide protons and electrons.

### BRIEF DESCRIPTION OF THE DRAWINGS

FIG. 1 depicts a schematic diagram of a portion of a fuel cell circuit in accordance with an illustrative embodiment of the present invention.

FIG. 2 depicts a schematic diagram of details of a fuel cell in accordance with the illustrative embodiment of the present invention.

FIG. 3 depicts a schematic diagram of a fuel cell in accordance with an alternative embodiment of the present invention.

Method 400 depicts a method for forming a fuel cell in accordance with the illustrative embodiment of the present invention.

Method 500 depicts a method for forming a fuel cell in accordance with an alternative embodiment of the present invention.

### DETAILED DESCRIPTION

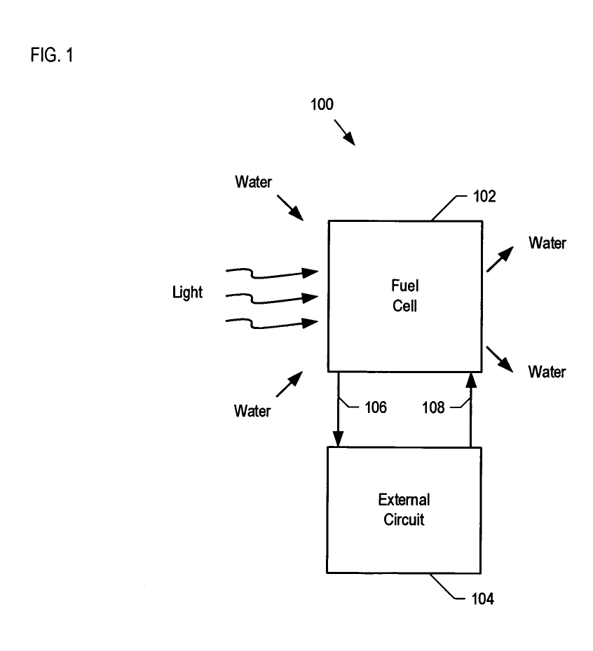

FIG. 1 depicts a schematic diagram of a portion of a fuel cell circuit in accordance with an illustrative embodiment of the present invention. Fuel cell circuit 100 comprises fuel cell 102 and external circuit 104.

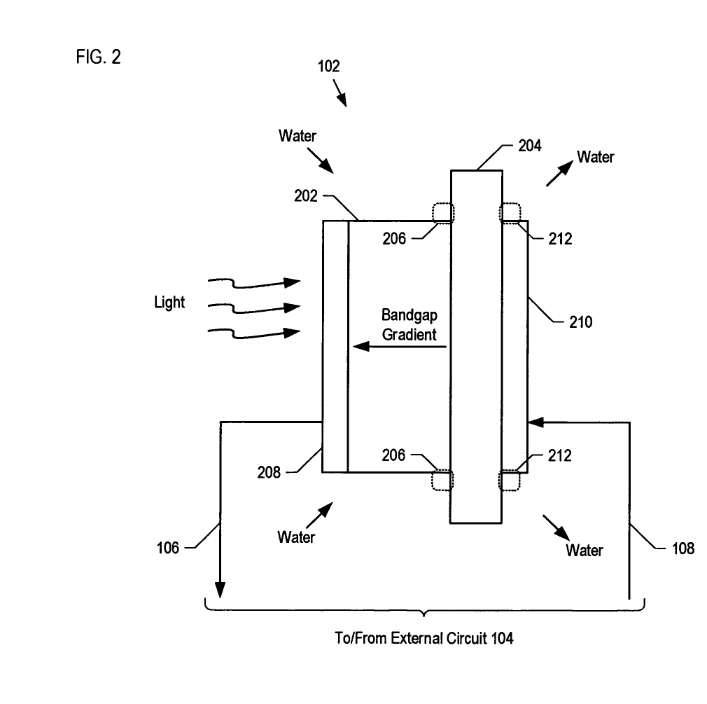

Fuel cell 102 is a photolytic fuel cell that absorbs light characterized by a wavelength within a range of suitable wavelengths. Fuel cell 102 utilizes the energy gained from absorbed light to dissociate water molecules into oxygen, protons, and electrons. Electrons liberated by fuel cell 102 are provided to external circuit 104 on wire 106. Electrons return to fuel cell 102 from external circuit 104 on wire 108. Fuel cell 102 recombines electrons that return on wire 108 with protons and oxygen to reform water molecules. Fuel cell 102 will be described in more detail below and with respect to FIG. 2.

External circuit 104 is an electronics circuit that has well-known functionality. It will be clear to those skilled in the art how to make and use external circuit 104.

FIG. 2 depicts a schematic diagram of details of a fuel cell in accordance with the illustrative embodiment of the present invention. Fuel cell 102 comprises photolytic layer 202, proton-conducting layer 204, anode 208, and cathode 210.

Method 400 depicts a method for forming a fuel cell in accordance with the illustrative embodiment of the present invention. Method 400 comprises operations suitable for the formation of fuel cell 102. The fabrication of fuel cell 102 is described below and with respect to FIGS. 1-2.

Method 400 begins with operation 401, wherein photolytic layer 202 is formed. Photolytic layer 202 is a layer of manganese-oxide that has a thickness suitable absorbing a desired amount of incident visible light. Typically, the thickness of photolytic layer 202 is within the range of approximately 2 nanometers to approximately 1 micron. In some embodiments, photolytic layer is suitable for absorbing solar radiation. Photolytic layer 202 is modified to create an anion-vacancy gradient through the thickness of the layer. The anion-vacancy gradient results in an energy-bandgap gradient through the thickness of the material. In some embodiments, the energy bandgap varies from a high bandgap of approximately five (5) electron-volts at anode 208 to a low bandgap of substantially zero at the interface of photolytic layer 202 and proton-conducting layer 204. In some embodiments of the present invention the energy bandgap varies from a high bandgap of approximately 2.5 electron-volts at anode 208 to a low bandgap of substantially zero at the interface of photolytic layer 202 and proton-conducting layer 204. In some embodiments, the energy bandgap varies from its high bandgap to a low bandgap that is higher than substantially zero.

Photolytic layer 202 is modified to have a high anion-vacancy concentration gradient by heating it to a temperature above 300° C. and applying an electric field of at least 10⁶ Volts/cm across the oxide. In order to quench the anion-vacancy concentration gradient in the oxide, photolytic layer 202 is cooled to a temperature below 100° C. while maintaining this electric field. In some embodiments, the anion-vacancy concentration gradient is quenched in the oxide by rapidly cooling photolytic layer 202 to a temperature below 100° C. without maintaining the applied electric field.

In some embodiments, photolytic layer 202 is not modified to have an anion vacancy gradient.

Although the illustrative embodiment comprises a photolytic layer that comprises an oxide, it will be clear to those skilled in the art, after reading this specification, how to make and use embodiments of the present invention wherein photolytic layer 202 comprises a semiconductor. Semiconductors suitable for use in photolytic layer 202 include, without limitation, silicon, germanium, III-V compound semiconductors, II-VI compound semiconductors, and sulfides (e.g., lead sulfide, etc.). It will also be clear to one of ordinary skill in the art, after reading this specification, how to make and use embodiments of the present invention wherein photolytic layer 202 comprises solid-oxide film different than manganese oxide. Suitable oxide films for use in photolytic layer 202 include, without limitation, titania, zirconia, tin oxide, tungsten oxide, iron oxide, and strontium titanate. In addition, it will be clear to those skilled in the art, after reading this specification, how to make and use embodiments of the present invention wherein photolytic layer 202 absorbs wavelengths of light other than those in the visible light spectrum.

Although the illustrative embodiment of the present invention comprises a photolytic layer that is electrically-conductive and conducts protons, it will be clear to those skilled in the art, after reading this specification, how to make and use embodiments of the present invention wherein photolytic layer 202 is either a) conductive for electrons, but not protons, or b) nonconductive for electrons and non-conductive for protons, or c) is electrically conductive but non-conductive for protons.

In some embodiments, photolytic layer 202 includes nanostructure to a) increase the light absorbing area and/or b) increase the surface area on which the dissociation of water molecules can occur.

In some embodiments, photolytic layer 202 includes dopants such as sulfur, nitrogen, and the like, to modify the bandgap of the layer or sub-layers.

In some embodiments wherein photolytic layer 202 is non-conductive for both electrons and protons, an electron and proton conducting layer is provided between photolytic layer 202 and proton-conducting layer 204. Suitable materials for this electron and proton conducting layer include, without limitation, palladium, Ca—GdNbO₄, Ca—Tb₂O₃, and Ca—LaNbO₄.

In some embodiments wherein photolytic layer 202 is electrically conductive but not conductive for protons, proton-conducting channels are included in photolytic layer 202 to conduct protons to proton-conducting layer 204.

At operation 402, proton-conducting layer 204 is formed. Proton-conducting layer 204 is a layer of yttrium-barium zirconate that has a thickness suitable for providing a desired level of electron impermeability. Typically, the thickness of proton-conducting layer 204 is within the range of approximately 5 nanometers to approximately 1 micron. Proton-conducting layer 204 is in intimate contact with photolytic layer 202 and conducts protons from photolytic layer 202 to cathode 210. In some embodiments, an oxygen ion conducting layer is formed at operation 402, rather than proton-conducting layer 204.

Although in the illustrative embodiment, proton-conducting layer 204 comprises a layer of yttrium-barium zirconate, it will be clear to those skilled in the art, after reading this specification, how to make and use embodiments of the present invention wherein proton-conducting layer 204 comprises any material that conducts protons but is substantially non-conductive for electrons. Suitable materials for use in proton-conducting layer 204 include, without limitation, proton conducting oxides, proton-conducting polymers, porous zeolites, and proton-conducting inorganic particles such as clay.

Triple-phase boundary 206 exists at the edge of the junction between photolytic layer 202 and proton-conducting layer 204. Triple-phase boundary 206 is a region of high reactivity for the various reactions associated with the dissociation of water (in either liquid- or gas-phase) into sub-components that include protons, electrons, oxygen, and ionized O-H molecules (i.e., hydroxide). Hydroxide further dissociates into protons and doubly-ionized oxygen atoms, which subsequently give up their electrons and form O₂ molecules. Although triple-phase boundary 206 is a region of particularly high reactivity, each of these reactions can occur anywhere on the exposed surfaces of photolytic layer 202.

At operation 403, anode 208 is formed on photolytic layer 202. Anode 208 is an electrode comprising indium-tin-oxide, and provides egress to external circuit 104 for electrons that are liberated by the dissociation of water molecules. Other suitable materials for use in anode layer 208 include, without limitation, transparent conductive oxides, and transparent metals. Anode 208 is transparent for the wavelengths of light in the visible light spectrum. In some embodiments, anode 208 comprises a material that is not transparent to visible light. In these embodiments, the total area of anode 208 is kept as small as possible so as to block as little as possible of the light incident upon fuel cell 102.

At operation 404, cathode 210 is formed on proton-conducting layer 204. Cathode 210 is an electrode comprising metallization and a catalyst for increasing the rate at which protons, oxygen, and electrons react to form water molecules. Region 212 is a region of high reactivity for recombination of protons, electrons, oxygen into water molecules (in either liquid- or gas-phase). This recombination reaction can, however, occur on any exposed surface of proton-conducting layer 204. In some embodiments, wherein the catalyst comprises a water-permeable material, recombination can occur on any surface of the proton-conducting layer. Cathode 210 provides ingress for electrons returning from external circuit 104. In order to increase the probability of light being absorbed in photolytic layer 202, cathode 210 comprises a material having high reflectivity for visible light. Photons that pass completely through photolytic layer 202 are, therefore, reflected. This increases the probability of that the photons will be absorbed. In some embodiments, cathode 210 includes nanostructure to scatter light back into photolytic layer 202. In some embodiments, cathode 210 does not comprise a catalyst.

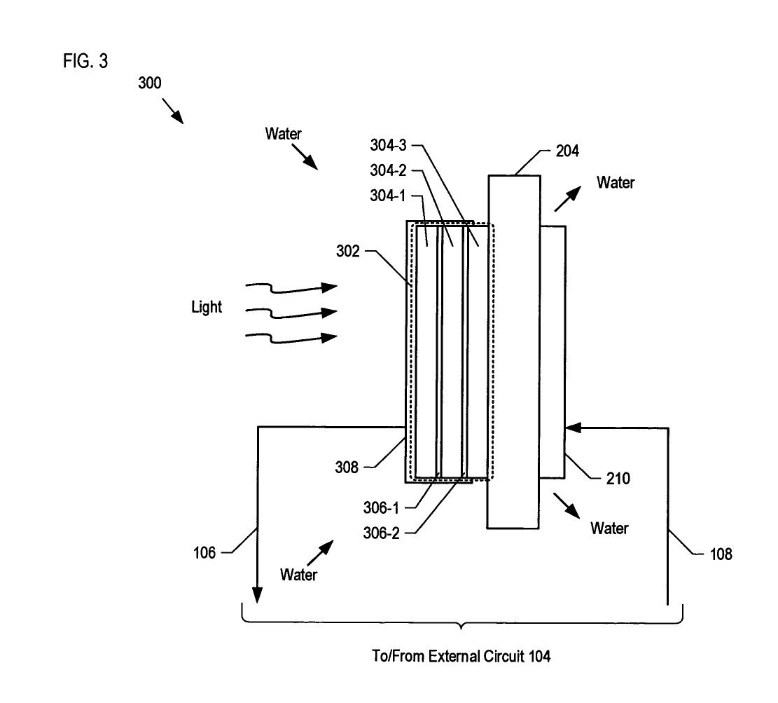

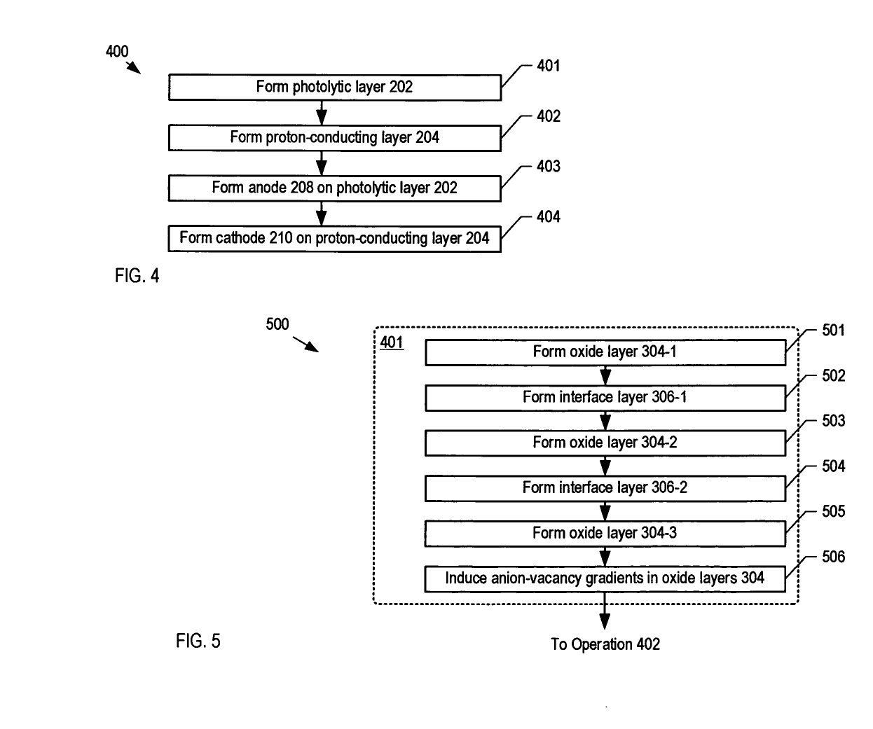

FIG. 3 depicts a schematic diagram of a fuel cell in accordance with an alternative embodiment of the present invention. Fuel cell 300 comprises photolytic layer 302, anode 308, proton-conducting layer 204, and cathode 210.

Method 500 depicts a method for forming a fuel cell in accordance with an alternative embodiment of the present invention. Method 500 comprises operations suitable for the formation of fuel cell 300. Collectively, the operations of method 500 are analogous to operation 401 of method 400. The fabrication of fuel cell 300 is described below and with continuing reference to FIG. 3.

Photolytic layer 302 comprises a plurality of sub-layers 304-1 through 304-3 (hereinafter referred to, collectively, as sub-layers 304), each of which comprises a solid oxide. Sub-layers 304-1 through 304-3 are interposed by interface layers 306-1 and 306-2 (hereinafter referred to, collectively, as interface layers 306), each of which comprises a layer of transparent electron-conducting material. Typically, the thickness of each of sub-layers 304 is within the range of approximately 1 nanometer to approximately 1 micron.

At method 501, sub-layer 304-1 is formed. Sub-layer 304-1 is a layer of manganese oxide, and is analogous to photolytic layer 202.

At method 502, interface layer 306-1 is disposed on sub-layer 304-1. Interface layer 306-1 is a layer of indium-tin-oxide. Sub-layers 304 are provided with electron-conducting interface layers 306 to enable sequential boosting of the electron energy. In some embodiments, interface layers 306:
i. reduce electron back transfer; or
ii. increase electron transfer while reducing energy loss; or
iii. provide band matching between sub-layers; or
iv. conduct electrons so as to provide sequential boosting of electron energy; or
v. improve the absorption absorbed light; or
vi. any combination of i, ii, iii, iv, and v.

At operation 503, oxide layer 304-2 is disposed on interface layer 306-1.

At operation 504, interface layer 306-2 is disposed on oxide layer 304-2.

At operation 505, oxide layer 304-3 is disposed on interface layer 306-2.

It will be apparent to one of ordinary skill in the art that any number of oxide layers and interface layers can be provided to collectively form photolytic layer 302.

At operation 506, an anion-vacancy gradient is induced in each of oxide layers 304.

It should be noted that operation 506 can be performed multiple times during the fabrication of photolytic layer 302. For example, operation 506 could be performed after the formation of each oxide layer 304 to induce an individualized anion-vacancy gradient in each layer. It should also be noted that each oxide layer 304 can be deposited in a manner to produce an in-situ anion-vacancy gradient, thereby obviating the need for operation 506.

The respective bandgaps of sub-layers 304 collectively provide a bandgap gradient in photolytic layer 302. Specifically, the bandgaps of sub-layer 304 vary from approximately 3 electron-volts for sub-layer 304-1 to substantially zero for sub-layer 304-4. In some embodiments, at least some of sub-layers 304 are modified to form an anion-vacancy gradient (and, therefore, a bandgap gradient) within themselves. In some embodiments, at least some of sub-layers 304 are modified such that these sub-layers absorb different wavelength spectra, thereby increasing the number of wavelengths that sub-layers 304 collectively absorb. In some embodiments, at least some of sub-layers 304 are modified so that sub-layers 304 collectively absorb a substantially continuous portion of a light spectrum, such as the visible light spectrum.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. An apparatus comprising:
a photolytic layer, wherein the photolytic layer is in a solid state; and
a proton-conducting layer, wherein the proton-conducting layer is in a solid state, and wherein the proton-conducting layer is substantially non-conductive for electrons;
wherein at least one of water and hydroxide molecules dissociate at a surface of the photolytic layer to provide protons and electrons.

2. The apparatus of claim 1 wherein the proton-conducting layer comprises an oxide.

3. The apparatus of claim 1 wherein the proton-conducting layer comprises an oxide selected from the group consisting of manganese oxide, titania, zirconia, tin oxide, tungsten oxide, iron oxide, and strontium titanate.

4. The apparatus of claim 1 further comprising a catalyst for increasing the rate of a chemical reaction wherein protons, oxygen, and electrons combine to form water molecules.

5. The apparatus of claim 4 further comprising a cathode, wherein the cathode comprises the catalyst.

6. The apparatus of claim 1 wherein the photolytic layer is characterized by a bandgap gradient that is based on an anion-vacancy gradient, and wherein the bandgap gradient comprises a maximum bandgap that is greater than or equal to 1.0 electron-volts.

7. The apparatus of claim 1 wherein the photolytic layer comprises a plurality of sub-layers for absorbing light, wherein each of the plurality of sub-layers is characterized by an anion-vacancy concentration, and further wherein each of the plurality of sub-layers is characterized by a bandgap gradient that comprises a maximum bandgap that is less than or equal to 2.0 electron-volts.

8. The apparatus of claim 1 wherein the photolytic layer comprises a plurality of sub-layers for absorbing light, wherein each of the plurality of sub-layers is characterized by an anion-vacancy concentration, and further wherein the plurality of sub-layers includes at least two sub-layers that are characterized by a different bandgap.

9. The apparatus of claim 1 wherein the photolytic layer comprises a plurality of sub-layers for absorbing light, wherein each of the plurality of sub-layers is characterized by an anion-vacancy concentration, and further wherein each of the plurality of sub-layers is characterized a bandgap that is substantially equal.

10. A method of forming a fuel cell comprising forming a photolytic layer for absorbing light having a wavelength within the solar spectrum, wherein the photolytic layer is formed by:
forming a first layer having an anion-vacancy concentration gradient;
wherein a surface of the photolytic layer enables the dissociation of at least one of water and O—H molecules to provide protons and electrons.

11. The method of claim 10 wherein the first layer is formed by operations comprising:
forming an oxide layer; and
modifying the oxide layer to create the anion-vacancy concentration gradient in the oxide layer.

12. The method of claim 11 wherein the oxide layer is modified by:
heating the oxide layer to a temperature greater than 300 degrees centigrade;
applying an electric field across the oxide layer, wherein the electric field exceeds 10⁸ Volts per meter; and
cooling the oxide layer to a temperature below 100 degrees centigrade.

13. The method of claim 12 wherein the oxide layer is cooled while maintaining the electric field.

14. The method of claim 12 wherein the oxide layer is cooled at a rate greater than 10 degrees centigrade per minute.

15. The method of claim 10 further comprising:
forming a proton-conducting layer, wherein the proton-conducting layer is substantially non-conductive for electrons, and wherein the proton-conducting layer and the photolytic layer are physically coupled;
forming an anode on a surface of the photolytic layer, wherein the anode is physically-adapted to provide egress for the electrons to an electronic circuit; and
forming a cathode on a surface of the proton-conducting layer, wherein the proton-conducting layer interposes the photolytic layer and the cathode, and wherein the cathode is physically-adapted to provide ingress for electrons from the external circuit.

16. The method of claim 15 further comprising providing a catalyst for increasing the rate of a chemical reaction wherein protons, oxygen, and electrons combine to form water molecules, wherein the catalyst and the cathode are integrated.

17. The method of claim 16 further comprising providing a catalyst for increasing the rate of a chemical reaction wherein protons, oxygen, and electrons combine to form water molecules, wherein the cathode comprises the catalyst.

18. The method of claim 10 wherein forming the oxide layer comprises forming a plurality of oxide sub-layers, and wherein at least one sub-layer of the plurality of oxide sub-layers has an anion-vacancy concentration.

19. The method of claim 18 wherein each of the plurality of oxide sub-layers has an anion-vacancy concentration gradient.

20. The method of claim 10 wherein forming the oxide layer comprises forming a plurality of oxide sub-layers, and wherein the plurality of oxide sub-layers collectively has an anion-vacancy concentration.
